(19) United States
(12) Patent Application Publication
(10) Pub. No.: US 2024/0213064 A1
(43) Pub. Date: Jun. 27, 2024

(54) SUBSTRATE PROCESSING SYSTEM, CONTROL DEVICE, AND SUBSTRATE TRANSFER PROCESSING METHOD

(71) Applicant: Tokyo Electron Limited, Tokyo (JP)

(72) Inventors: Minoru NAGASAWA, Tokyo (JP); Toshiharu HIRATA, Nirasaki City (JP); Takafumi MATSUHASHI, Nirasaki City (JP)

(21) Appl. No.: 18/390,547

(22) Filed: Dec. 20, 2023

(30) Foreign Application Priority Data
Dec. 21, 2022 (JP) 2022-204846

(51) Int. Cl. H01L 21/67

(52) U.S. Cl. CPC H01L 21/67276; H01L 21/67167; H01L 21/67184

(57) ABSTRACT

A substrate processing system includes: one or more transfer modules configured to transfer substrates; a plurality of process modules configured to perform a substrate processing on the substrates transferred by the one or more transfer modules; and a control device configured to control the one or more transfer modules and the plurality of process modules, wherein the control device sequentially performs: calculating a substrate supply interval for supplying the substrates so that substrate transfer periods during which the substrates are transferred do not overlap with each other; and equalizing, based on the calculated substrate supply interval, a plurality of time intervals between the substrate transfer periods so that the substrate transfer periods are separated from each other.

### CROSS-REFERENCE TO RELATED APPLICATION

This application is based upon and claims the benefit of priority from Japanese Patent Application No. 2022-204846, filed on Dec. 21, 2022, the entire contents of which are incorporated herein by reference.

### TECHNICAL FIELD

The present disclosure relates to a substrate processing system, a control device, and a substrate transfer processing method.

### BACKGROUND

In the related art, there is known a substrate processing system that sequentially transfers substrates to a plurality of process modules by a plurality of transfer modules and performs substrate processing on the substrates. In this type of substrate processing system, in order to make uniform the thermal history of the substrates, one cycle time is set, and the transfer of the substrates by each transfer module and the processing of the substrates by each process module are performed in cycle time units.

However, if a processing delay occurs in a certain module, the transfer device of the transfer module will not be able to transfer the substrates in time, resulting in confusion in the transfer of the substrates by the transfer module. Therefore, the substrate processing system copes with the processing delay by setting a waiting time in the cycle time at which the processing delay is allowable.

### Prior Art Document

### [Patent Document]

Patent Document 1: Japanese Laid-Open Patent Publication No. 2022-052165
Patent Document 2: Japanese Laid-Open Patent Publication No. 2022-076547

### SUMMARY

According to one embodiment of the present disclosure, a substrate processing system includes: one or more transfer modules configured to transfer substrates; a plurality of process modules configured to perform a substrate processing on the substrates transferred by the one or more transfer modules; and a control device configured to control the one or more transfer modules and the plurality of process modules, wherein the control device sequentially performs: calculating a substrate supply interval for supplying the substrates so that substrate transfer periods during which the substrates are transferred do not overlap with each other; and equalizing, based on the calculated substrate supply interval, a plurality of time intervals between the substrate transfer periods so that the substrate transfer periods are separated from each other.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a substrate processing system according to a first configuration example of the present embodiment.

FIG. 2 is a block diagram showing a configuration example of hardware of a control device of the substrate processing system.

FIG. 3 is a plan view schematically showing a substrate processing system according to a second configuration example of the present embodiment.

FIG. 4A is a flowchart showing a processing flow of a substrate transfer processing method, and FIG. 4B is a diagram for explaining a wafer supply interval.

FIG. 5 is a diagram showing a first transfer period, a second transfer period, a first TM use interval, and a second TM use interval included in the wafer supply interval.

FIG. 6A is an enlarged plan view showing a configuration of a fourth transfer module and its surroundings in the substrate processing system according to the second configuration example, and FIG. 6B is a diagram showing the wafer supply interval of the fourth transfer module.

FIG. 7A is a diagram showing a pattern in the fourth transfer module, and FIG. 7B is a diagram showing a pattern in the fourth transfer module.

FIG. 8A is a diagram for explaining formula (3), and FIG. 8B is a diagram showing an example in which the condition in formula (3) is not satisfied.

FIG. 9A is a diagram for explaining formula (4), FIG. 9B is a diagram showing an example in which the condition in formula (4) is not satisfied, and FIG. 9C is a diagram for explaining formula (5).

FIG. 10 is a diagram showing a plurality of patterns in the third transfer module.

FIG. 11A is a diagram for explaining formula (7), FIG. 11B is a diagram for explaining formula (8), and FIG. 11C is a diagram showing a period on the fourth transfer module side which is incorporated in the third transfer module.

FIG. 12A is a diagram for explaining formula (9), FIG. 12B is a diagram for explaining formula (10), and FIG. 12C is a diagram for explaining formula (11).

FIG. 13A is a diagram for explaining formula (12), FIG. 13B is a diagram for explaining formula (13), FIG. 13C is a diagram for explaining formula (15), and FIG. 13D is a diagram for explaining formula (16).

FIG. 14A is a diagram for explaining an example in which the wafer supply interval is longer than the actual period of a process recipe, FIG. 14B is a diagram for explaining formula (17), FIG. 14C is a diagram for explaining formula (18), and FIG. 14D is a diagram for explaining formula (19).

FIG. 15A is a diagram for explaining the equalization of use intervals of a transfer module, and FIG. 15B is a diagram for explaining the equalization of use intervals of the transfer module corresponding to an immediate unloading process module.

### DETAILED DESCRIPTION

Hereinafter, embodiments for implementing the present disclosure will be described with reference to the drawings. In each drawing, the same components are designated by like reference numerals, and redundant explanations thereof are omitted in some cases. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

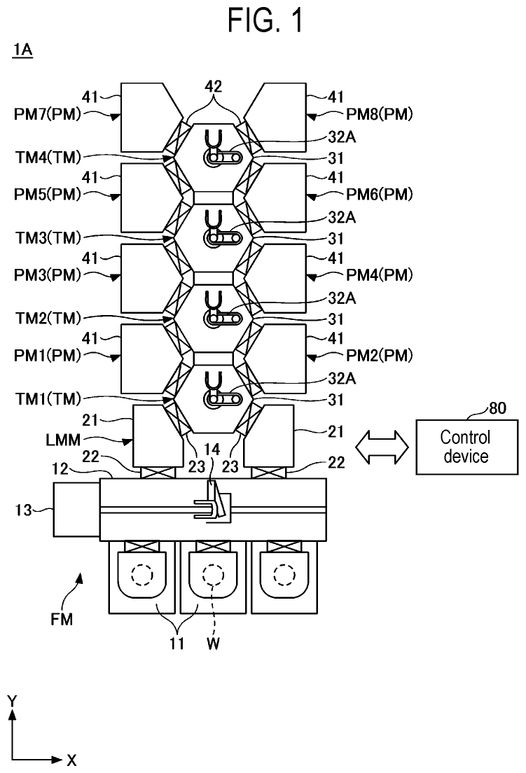

FIG. 1 is a plan view schematically showing a substrate processing system 1A according to a first configuration example of the present embodiment. As shown in FIG. 1, the substrate processing system 1A is configured as a multi-chamber type having a plurality of process modules PM. The substrate processing system 1A is used in one of semiconductor manufacturing processes. A plurality of transfer modules TM sequentially transfer substrates to the respective process modules PM. An appropriate substrate processing is performed within each process module PM.

Examples of the substrate to be subjected to substrate processing include a silicon semiconductor wafer, a compound semiconductor wafer, an oxide semiconductor wafer, or the like (hereinafter also referred to as wafer W). The wafer W may have a pattern of recesses such as trenches and vias. Further, the substrate processing performed by the process module PM include a film-forming process, an etching process, an ashing process, a cleaning process, and the like.

The substrate processing system 1A loads the wafer W from an air atmosphere to a vacuum atmosphere, performs a substrate processing on the wafer W in each transfer module TM and each process module PM kept in the vacuum atmosphere, and unloads the wafer W from the vacuum atmosphere to the air atmosphere after the substrate processing. Therefore, the substrate processing system 1A includes a front module FM (e.g., Equipment Front End Module: EFEM) that transfers the substrate in the air atmosphere, and a load lock module LLM that switches between the air atmosphere and the vacuum atmosphere. The substrate processing system 1A further includes a control device 80 that controls the front module FM, the load lock module LLM, the respective process modules PM, and the respective transfer modules TM.

The front module FM includes a plurality of load ports 11, one loader 12 adjacent to each load port 11, and an alignment device 13 (orienter) provided at a position adjacent to the loader 12. Each load port 11 is set with a FOUP (Front Opening Unified Pod) that stores a plurality of wafers W after a previous manufacturing process, and an empty FOUP that stores wafers W that have undergone substrate processing in the substrate processing system 1A.

The loader 12 is formed into a rectangular box having a cleaning space therein. The front module FM includes an atmosphere-side transfer device 14 inside the loader 12. atmosphere-side

The atmosphere-side transfer device 14 takes out the wafer W from the FOUP set in each load port 11 and transfers the wafer W to the alignment device 13 via the cleaning space inside the loader 12. Further, the atmosphere-side transfer device 14 loads the wafer W taken out from the alignment device 13 into the load lock module LLM. Further, the atmosphere-side transfer device 14 unloads the wafer W subjected to the substrate processing from the load lock module LLM, and stores the wafer W in the FOUP via the cleaning space in the loader 12.

The alignment device 13 measures the amount of eccentricity of the wafer W by detecting the position of the outer edge of the wafer W while rotating the wafer W. The alignment device 13 and the atmosphere-side transfer device 14 adjust the circumferential position of the wafer W, the posture of the wafer W supported by the atmosphere-side transfer device 14, and the like based on the measured amount of eccentricity.

Two load lock modules LLM are provided between the front module FM and the transfer module TM. Each load lock module LLM has a load lock container 21 that may temporarily accommodate wafers W. A gate 22 including a valve body (not shown) that airtightly closes the load lock container 21 is provided between the load lock module LLM and the front module FM. Further, a gate 23 including a valve body (not shown) that airtightly closes the load lock container 21 is provided between the load lock module LLM and the transfer module TM.

For example, one of the two load lock modules LLM (left one in FIG. 1) accommodates the wafer W loaded from the front module FM in the air atmosphere, and then reduces the pressure to the vacuum atmosphere, thereby making it possible to transfer the wafer W to the transfer module TM. The other of the two load lock modules LLM (the right one in FIG. 1) accommodates the wafer W loaded from the transfer module TM in the vacuum atmosphere and then increases the air atmosphere, thereby making it possible to transfer the wafer W to the front module FM. The substrate processing system 1A may be configured to include only one load lock module LLM (load lock container 21). In this case, the load lock container 21 may have a configuration in which a space for loading the wafer W from the front module FM to the transfer module TM and a space for unloading the wafer W from the transfer module TM to the front module FM are separated in the up-down direction (vertical direction).

The substrate processing system 1A according to the present embodiment includes a plurality of (four) transfer modules TM installed side by side in the Y-axis direction, and a plurality of (eight) process modules PM installed at positions adjacent to the respective transfer modules TM. Hereinafter, the plurality of transfer modules TM will be referred to as a first transfer module TM1, a second transfer module TM2, a third transfer module TM3, and a fourth transfer module TM4 sequentially toward the Y-axis positive direction.

On the other hand, four process modules PM are installed on the left side of the transfer module group (on the X-axis negative direction side) so as to correspond to the four transfer modules TM, and four process modules PM are installed on the right side of the transfer module group (the X-axis positive direction side). In the following, by taking FIG. 1 as an example, the respective process modules PM installed on the left side of the respective transfer modules TM will be referred to as a left row process module group, and the respective process modules PM installed on the right side of the respective transfer modules TM will be referred to as a right row process module group. The left row process module group and the right row process module group extend parallel to the transfer module group.

The left row process module group includes a first process module PM1, a third process module PM3, a fifth process module PM5, and a seventh process module PM7 sequentially in the Y-axis positive direction. The right row process module group includes a second process module PM2, a fourth process module PM4, a sixth process module PM6, and an eighth process module PM8 sequentially in the Y-axis positive direction.

The first process module PMI is arranged on the left side and in the middle of the first transfer module TM1 and the second transfer module TM2, and is connected to the first transfer module TM1 and the second transfer module TM2. The second process module PM2 is arranged on the right side and in the middle of the first transfer module TM1 and the second transfer module TM2, and is connected to the first transfer module TM1 and the second transfer module TM2.

The third process module PM3 is arranged on the left side and in the middle of the second transfer module TM2 and the third transfer module TM3, and is connected to the second transfer module TM2 and the third transfer module TM3. The fourth process module PM4 is arranged on the right side and in the middle of the second transfer module TM2 and the third transfer module TM3, and is connected to the second transfer module TM2 and the third transfer module TM3.

The fifth process module PM5 is arranged on the left side and in the middle of the third transfer module TM3 and the fourth transfer module TM4, and is connected to the third transfer module TM3 and the fourth transfer module TM4. The sixth process module PM6 is arranged on the right side and in the middle of the third transfer module TM3 and the fourth transfer module TM4, and is connected to the third transfer module TM3 and the fourth transfer module TM4.

The seventh process module PM7 is arranged on the left side of the fourth transfer module TM4 and is connected to the fourth transfer module TM4. The eighth process module PM8 is arranged on the right side of the fourth transfer module TM4 and is connected to the fourth transfer module TM4.

Each transfer module TM includes a transfer container 31 that may be depressurized to a vacuum atmosphere, and a transfer robot 32A installed within the transfer container 31. The transfer container 31 is formed into a hexagonal box shape in a plan view. The two load lock modules LLM, the first process module PM1, and the second process module PM2 are connected to predetermined sides of the transfer container 31 of the first transfer module TM1, respectively. The first to fourth process modules PMI to PM4 are connected to predetermined sides of the transfer container 31 of the second transfer module TM2. The third to sixth process modules PM3 to PM6 are connected to predetermined sides of the transfer container 31 of the third transfer module TM3, respectively. The fifth to eighth process modules PM5 to PM8 are connected to predetermined sides of the transfer container 31 of the fourth transfer module TM4, respectively.

The transfer robot 32A is configured to be movable in the horizontal and vertical directions within the transfer container 31, and to be rotatable by θ in the horizontal direction. The transfer robot 32A includes one pick (end effector) constituted by a bifurcated fork, and holds the wafer W horizontally. The transfer robots 32A provided in the first transfer module TM1 to the fourth transfer module TM4 may operate independently of each other under the control of the control device 80. The transfer robot 32A delivers and receives the wafers W by moving forward and backward with respect to the modules (the two load lock modules LLM and the first process module PM1 to the eighth process module PM8) adjacent to the transfer container 31.

On the other hand, each of the plurality of process modules PM includes a processing container 41 that accommodates a wafer W therein and performs a substrate processing. The processing container 41 is formed in a polygonal shape (pentagonal shape) when viewed from above. Gates 42 are provided between the transfer container 31 and the respective processing containers 41 to communicate with the spaces thereof and allow the wafer W to pass therethrough. A valve (not shown) for opening and closing the processing container 41 is installed inside each of the gates 42.

Further, each process module PM includes a stage (not shown) provided inside the processing container 41 so that the wafer W may be placed on the stage. The stage includes a plurality of lift pins (not shown). The stage receives the wafer W from the transfer robot 32A and delivers the wafer W to the transfer robot 32A based on the up/down movement of the lift pins.

The substrate processing performed by each process module PM may be any of the film-forming process, the etching process, the ashing process, the cleaning process, and the like described above. The substrate processing system 1A may be configured such that the first process module PM1 to the eighth process module PM8 perform different substrate processing, or may perform the same substrate processing.

The above-described substrate processing system 1A may be used, for example, to manufacture a laminated film (MTJ film) used for a MRAM (Magneto-resistive Random Access Memory). There are multiple substrate processing such as a pre-cleaning process, a film-forming process, an oxidation process, a heating process, and a cooling process in the manufacture of the MTJ film. These processes are performed in the first process module PM1 to the eighth process module PM8. One or more of the first process module PMI to the eighth process module PM8 may be a standby module in which the wafer W is kept on standby.

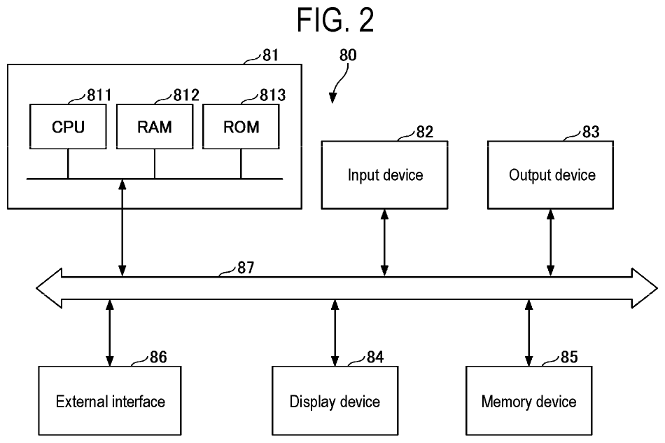

FIG. 2 is a block diagram showing a configuration example of hardware of the control device 80 of the substrate processing system 1A. As shown in FIG. 2, the control device 80 of the substrate processing system 1A includes a main controller 81, an input device 82, an output device 83, a display device 84, a memory device 85, an external interface 86, and a bus 87 that connects them. The input device 82 is a keyboard, a mouse, a touch panel or the like. The output device 83 is a printer or the like. The display device 84 is a display (including a touch panel) or the like.

The main controller 81 includes a CPU (Central Processing Unit) 811, a RAM (Random Access Memory) 812, and a ROM (Read Only Memory) 813. The memory device 85 has a storage medium such as an HDD (Hard Disk Drive) or the like from which information may be read, and stores information such as programs necessary for control and recipes for processing the wafer W. The substrate processing system 1A performs various processes on the wafer W as he CPU 811 executes the programs stored in the ROM 813 or the memory device 85 by using the RAM 812 as a work area.

Returning to FIG. 1, the control device 80 of the substrate processing system 1A may be configured, for example, to perform substrate processing by serially transferring wafers W in a U-shape in each transfer module TM and each process module PM. That is, the wafer W is transferred from the left load lock module LLM to the first process module PMI by the first transfer module TM1, and is subjected to a substrate processing in the first process module PM1. After the substrate processing in the first process module PM1, the wafer W is transferred from the first process module PMI to the third process module PM3 by the second transfer module TM2, and is subjected to a substrate processing in the third process module PM3. After the substrate processing in the third process module PM3, the wafer W is transferred from the third process module PM3 to the fifth process module PM5 by the third transfer module TM3, and is subjected to a substrate processing in the fifth process module PM5. After the substrate processing in the fifth process module PM5, the wafer W is transferred from the fifth process module PM5 to the seventh process module PM7 by the fourth transfer module TM4, and is subjected to a substrate processing in the seventh process module PM7.

After the substrate processing in the seventh process module PM7, the wafer W is transferred from the seventh process module PM7 to the eighth process module PM8 by the fourth transfer module TM4, and is subjected to a substrate processing in the eighth process module PM8. After the substrate processing in the eighth process module PM8, the wafer W is transferred from the eighth process module PM8 to the sixth process module PM6 by the fourth transfer module TM4, and is subjected to a substrate processing in the sixth process module PM6. After the substrate processing in the sixth process module PM6, the wafer W is transferred from the sixth process module PM6 to the fourth process module PM4 by the third transfer module TM3, and is subjected to a substrate processing in the fourth process module PM4. After the substrate processing in the fourth process module PM4, the wafer W is transferred from the fourth process module PM4 to the second process module PM2 by the second transfer module TM2, and is subjected to a substrate processing in the second process module PM2. After the substrate processing in the second process module PM2, the wafer W is transferred from the second process module PM2 to the right load lock module LLM by the first transfer module TM1.

Thus, the substrate processing system 1A may sequentially perform eight substrate processing on the wafer W. However, the substrate processing system 1A does not wait to process the next wafer W until eight substrate processes have been completed for one wafer W. The wafer W is transferred to each of the plurality of process modules PM, and a substrate processing is performed on the wafer W in each process module PM. Therefore, in the substrate processing system 1A, basically, the processing processes of the wafers W in each process module PM and each transfer module TM are performed synchronously.

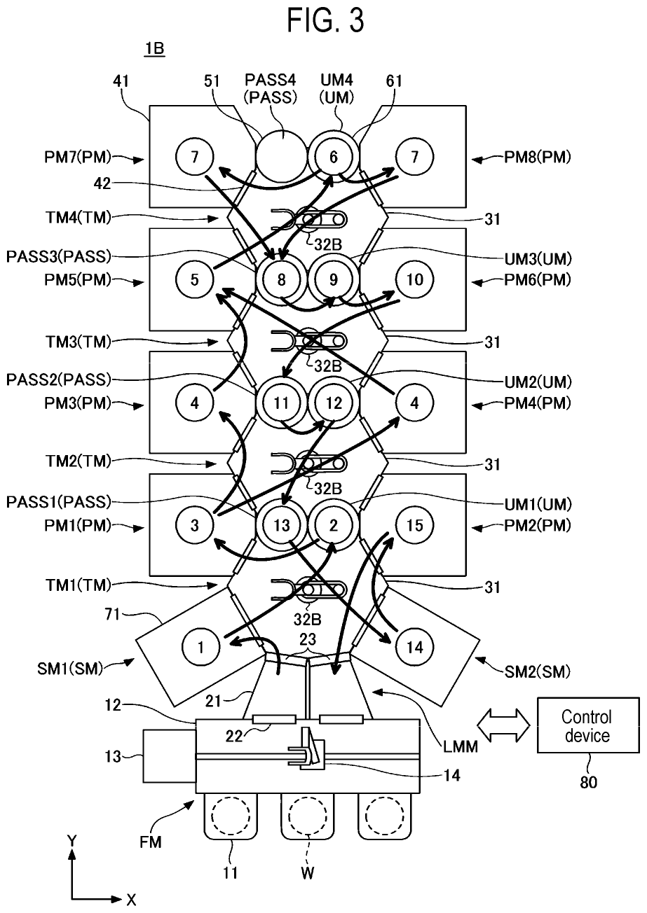

The substrate processing system 1A is not limited to the first configuration example described above, and may take various configuration examples. Next, a substrate processing system 1B according to a second configuration example will be described with reference to FIG. 3. FIG. 3 is a plan view schematically showing a substrate processing system 1B according to a second configuration example of the present embodiment.

Just like the substrate processing system 1A, the substrate processing system 1B includes a front module FM, a load lock module LLM, process modules PM, transfer modules TM, and a control device 80. The transfer modules TM are arranged side by side along the Y-axis direction to constitute a transfer module group. A first process module PM1, a third process module PM3, a fifth process module PM5, and a seventh process module PM7 are arranged on the left side of the transfer module group to constitute a left row process module group. A second process module PM2, a fourth process module PM4, a sixth process module PM6, and an eighth process module PM8 are arranged on the right side of the transfer module group to constitute a right row process module group. In the substrate processing system 1B, the same configurations or the configurations having the same functions as those of the substrate processing system 1A will be designated by like reference numerals, and the descriptions thereof will be omitted.

The substrate processing system 1B differs from the substrate processing system 1A shown in FIG. 1 in that it includes a plurality of storage modules SM, a plurality of passage modules PASS, and a plurality of retraction modules UM in addition to the plurality of process modules PM.

Further, the transfer robot 32B provided in each transfer module TM includes two picks (end effectors) capable of holding the wafer W. Thus, the transfer robot 32B is able to exchange (deliver and receive) wafers W with respect to the process module PM, the load lock module LLM, the storage module SM, the passage module PASS, the retraction module UM, and the like. For example, the transfer robot 32B may receive the wafer W with one pick while delivering the wafer W with another pick, with respect to each storage module SM.

The substrate processing system 1B includes one passage module PASS and one retraction module UM arranged between two transfer modules TM adjacent to each other in the Y-axis direction. The passage module PASS and the retraction module UM are arranged side by side in the X-axis direction on one side of the hexagonal transfer module TM.

The passage module PASS includes a cylindrical container 51 and a stage (not shown) provided within the container 51. The passage module PASS includes an openable/closable gate valve (not shown) arranged on each of the two transfer modules TM that are in contact with each other in the Y-axis direction. Hereinafter, the passage module arranged between the first transfer module TM1 and the second transfer module TM2 will be referred to as a first passage module PASS1, the passage module arranged between the second transfer module TM2 and the third transfer module TM3 will be referred to as a second passage module PASS2, the passage module arranged between the third transfer module TM3 and the fourth transfer module TM4 will be referred to as a third passage module PASS3, and the passage module arranged on the Y-axis positive direction side of the fourth transfer module TM4 will be referred to as a fourth passage module PASS4. The fourth passage module PASS4 is used when another transfer module (fifth transfer module) is applied to the fourth transfer module TM4, and is a module that is not used in the present embodiment.

The retraction module UM includes a cylindrical container 61 and a stage (not shown) provided within the container 61. The retraction module UM is provided with a gate valve (not shown) that may be opened and closed with respect to the transfer module TM which is in contact with the retraction module UM in the Y-axis negative direction. The retraction module UM is closed with respect to the transfer module TM which is in contact with the retraction module UM in the Y-axis positive direction. Hereinafter, the retraction module arranged between the first transfer module TM1 and the second transfer module TM2 will be referred to as a first retraction module UM1, the retraction module arranged between the second transfer module TM2 and the third transfer module TM3 will be referred to as a second retraction module UM2, the retraction module arranged between the third transfer module TM3 and the fourth transfer module TM4 will be referred to as a third retraction module UM3, and the retraction module arranged on the Y-axis positive direction side of the fourth transfer module TM4 will be referred to as a fourth retraction module UM4. The first retraction module UM1 allows wafers W to be loaded into and unloaded from the first transfer module TM1, the second retraction module UM2 allows wafers W to be loaded into and unloaded from the second transfer module TM2, the third retraction module UM3 allows wafers W to be loaded into and unloaded from the third transfer module TM3, and the fourth retraction module UM4 allows wafers W to be loaded into and unloaded from the fourth transfer module TM4.

On the other hand, the storage modules SM are connected to the left side and the right side of the first transfer module TM1 to which the first process module PM1 and the second process module PM2 are not connected. The storage module SM includes a rectangular housing 71 and a plurality of shelf boards (not shown) provided vertically within the housing 71, and may accommodate a plurality of wafers W in the vertical direction. The storage module SM stores unprocessed wafers W, processed wafers W, or wafers W in the middle of processing in the substrate processing system 1B. Hereinafter, the storage module arranged on the left side of the first transfer module TM1 will be referred to as a first storage module SM1, and the storage module arranged on the right side of the first transfer module TM1 will be referred to as a second storage module SM2.

Each storage module SM, each passage module PASS, and each retraction module UM simply mounts the wafer W after the wafer W is loaded, and allows a predetermined transfer robot 32B to take out the wafer W. However, each storage module SM, each passage module PASS, and each retraction module UM are not limited to having the simple mounting function, and may be configured to perform a predetermined substrate processing on the wafer W stored therein. For example, the substrate processing includes a process of adjusting the temperature of the wafer W (heating, cooling, or keeping warm the wafer W), a process of oxidizing the wafer W, a process of cleaning the wafer W, and the like.

Further, in the substrate processing system 1B, similarly to the substrate processing system 1A, the control device 80 controls the front module FM, the load lock module LLM, each process module PM, each transfer module TM, each storage module SM, and each passage module PASS, and each retraction module UM. In particular, the substrate processing system 1B does not transfer wafers W serially in a U-shape as in the substrate processing system 1A, but allows a user to arbitrarily set the transfer path of wafers W according to the content of the substrate processing in each process module PM, the stay period, and the like.

For example, in the example shown in FIG. 3, the wafer W loaded from the load lock module LLM into the first transfer module TM1 is transferred to the first storage module SM1, the first retraction module UM1, and the first process module PM1 in the named order. Then, a substrate processing for the wafer W is performed in the first process module PM1. After the substrate processing in the first process module PM1, the wafer W is selectively transferred by the second transfer module TM2 to the third process module PM3 or the fourth process module PM4 and is subjected to a substrate processing. In other words, the substrate processing system 1B has a configuration in which the same type of substrate processing is performed over a long period of time in the third process module PM3 and the fourth process module PM4, which makes it possible to perform selective transfer (hereinafter referred to as OR transfer). After the substrate processing in the third process module PM3 or the fourth process module PM4, the wafer W is transferred to the fifth process module PM5 by the third transfer module TM3 and subjected to a substrate processing. After the substrate processing in the fifth process module PM5, the wafer W is temporarily evacuated to the fourth retraction module UM4 by the fourth transfer module TM4. Then, the wafer is selectively transferred to the seventh process module PM7 or the eighth process module PM8 and subjected to a substrate processing.

After the substrate processing in the seventh process module PM7 or the eighth process module PM8, the wafer W is transferred to the third passage module PASS3 by the fourth transfer module TM4. Further, the wafer W is transferred by the third transfer module TM3 from the third passage module PASS3 to the sixth process module PM6 via the third retraction module UM3 and subjected to a substrate processing. After the substrate processing in the sixth process module PM6, the wafer W is transferred to the second passage module PASS2 by the third transfer module TM3. The wafer W is transferred by the second transfer module TM2 from the second passage module PASS2 to the first passage module PASS1 via the second retraction module UM2. The wafer W is then transferred by the first transfer module TM1 to the second storage module SM2, and is further transferred from the second storage module SM2 to the second process module PM2 and subjected to a substrate processing. After the substrate processing in the second process module PM2, the wafer W is transferred to the load lock module LLM by the first transfer module TM1.

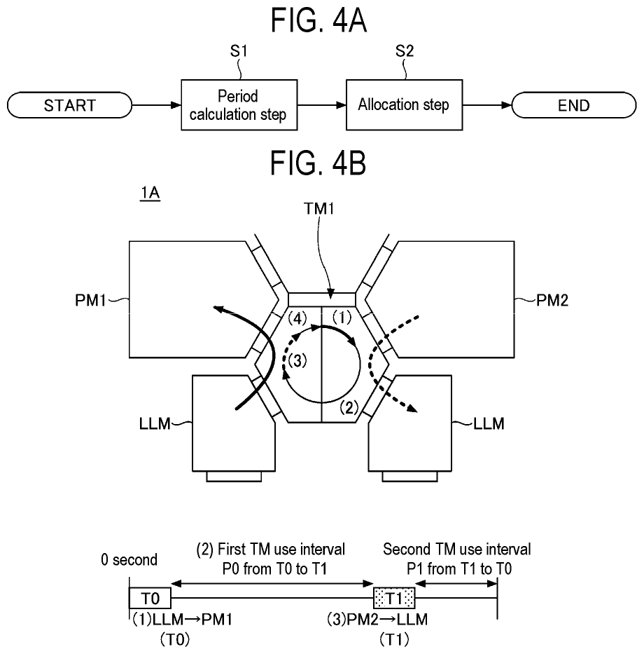

The substrate processing system 1B sequentially loads and unloads a plurality of wafers W from the air atmosphere side to the vacuum atmosphere side, transfers each wafer W along the above-mentioned transfer path, and performs a substrate processing in each process module PM. In the process (transfer process or substrate processing) of each wafer W, the control device 80 needs to perform control so that the transfer periods of the plurality of wafers W do not overlap with each other. Therefore, in the substrate transfer processing method, as shown in FIG. 4A, the control device 80 sets the schedule of a transfer process and a substrate processing by performing a period calculation step SI and an allocation step S2 in the named order. Then, the control device 80 executes the transfer process and the substrate processing based on the set schedule.

In the period calculation step S1, a supply interval of wafers (substrates) W is calculated so that the substrate transfer periods of a plurality of wafers W do not overlap in the same transfer module TM (transfer robot 32B). In this specification, the “supply interval of wafers W (substrates)” means the total period in which the entire transfer process (the transfer of the wafer W along the transfer path) performed by a predetermined transfer module TM is carried out once at time intervals. The next wafer W is supplied to the predetermined transfer module TM in accordance with the supply interval of wafers W. The supply interval of wafers W is also a cycle time in which the predetermined transfer module TM repeats the supply of wafers W periodically. In each transfer module TM, the control device 80 operates the transfer robots 32A and 32B in accordance with the supply interval of wafers W thus set, and repeats the supply interval of wafers W, thereby realizing sequential transfer of wafers W as a whole system.

For example, by taking the first transfer module TM1 (see FIG. 1) of the substrate processing system 1A as an example, the supply interval of wafers W will be described with reference to FIG. 4B. In the first transfer module TM1, there are a first transfer period T0 in which the wafer W is transferred from the load lock module LLM to the first process module PM1 and a second transfer period T1 in which the wafer W is transferred from the second process module PM2 to the load lock module LLM. Further, in the first transfer module TM1, a time interval (first TM use interval P0) of the first transfer module TM1 from the first transfer period T0 to the second transfer period T1 and a time interval (second TM use interval P1) of the first transfer module TM1 from the second transfer period T1 to the first transfer period T0 are involved. However, the transfer robot 32A of the first transfer module TM1 may be in a standby state during the first TM use interval and the second TM use interval. The TM use intervals are determined by the transfer period of other transfer modules TM and the stay period of a plurality of process modules PM.

In summary, the first transfer module TM1 of the substrate processing system 1A needs to take into account the first transfer period T0, the first TM use interval P0, the second transfer period T1, and the second TM use interval P1, and the sum of these periods and intervals is the supply interval of wafers W (cycle time) for the first transfer module TM1. However, since the first TM use interval P0 and the second TM use interval P1 are not related to the operation of the transfer robot 32A of the first transfer module TM1, they may be used as margin periods for the transfer robot 32A. In this case, the control device 80 may calculate a period longer than the first TM use interval P0 and the second TM use interval P1, and a supply interval of wafers W in which the first transfer period T0 and the second transfer period T1 do not overlap with each other.

Specifically, the control device 80 sets constraint conditions for each transfer module TM in which the transfer periods of the wafers W do not overlap, and changes the supply interval of wafers W and the stay period of wafers W in each process module PM based on these constraint conditions. Then, the control device 80 solves, as a linear programming problem, the supply interval of wafers W that provides the best throughput (the highest processing efficiency) in each transfer module TM.

That is, the control device 80 formulates, as a formula, the constraint conditions in which the transfer periods do not overlap with each other, for combinations of a plurality of types of transfer paths executed in the respective transfer modules TM. However, there are an infinite number of solution candidates that satisfy the formula of the constraint conditions. The control device 80 may obtain the supply interval of wafers W by using the throughput as an objective function and solving, as a mixed integer programming problem, a combination that provides the best throughput.

Further, in the allocation step S2, based on the supply interval of wafers W calculated in the period calculation step S1, the allocation of a plurality of transfer periods is calculated so as to be resistant to the delay in the stay period of the process module PM, and each of the transfer periods is scheduled. The expression “resistant to the delay in the stay period of the process module PM” refers to, for example, being able to transfer wafers W without overlapping a plurality of transfer periods even if the substrate processing time in the process module PM becomes long.

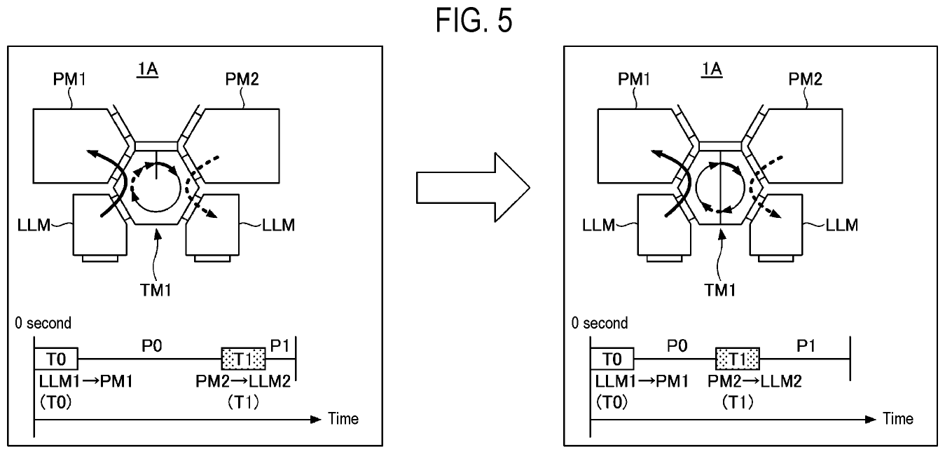

Hereinafter, by taking the first transfer module TM1 (see FIG. 1) of the substrate processing system 1A as an example, the allocation of a plurality of transfer periods will be described with reference to FIG. 5. As described above, there are two transfer periods (the first transfer period T0 and the second transfer period T1) in the supply interval of wafers W in the first transfer module TM1.

Here, it is considered that as shown in the left diagram of FIG. 5, the end of the second transfer period T1 is close to the start of the first transfer period T0 (the second transfer period T1 is close to the end point of the supply interval of wafers W). In this case, the second TM use interval P1 becomes shorter, and the first transfer period T0, which is the start of the supply interval of wafers W, is started after the second TM use interval P1. If the substrate processing in the first process module PM1 is delayed and the first TM use interval P0 becomes longer, the second transfer period T1 may be delayed to overlap with the first transfer period T0. In other words, if a plurality of transfer periods are close to each other in the supply interval of wafers W, it can be said that it is vulnerable to a delay in the stay period of the process module PM.

On the other hand, in the allocation of the two transfer periods shown in the right diagram of FIG. 5, the start/end of the second transfer period T1 is temporally separated from the start/end of the first transfer period T0. In this case, even if the stay period and the transfer period in each process module PM on the transfer path are delayed, it is possible to sufficiently reduce the possibility that the first transfer period T0 and the second transfer period T1 overlap with each other. In other words, if a plurality of transfer periods are separated from each other (sparse) in the supply interval of wafers W, it can be said that it is resistant to a delay in the stay period in the process module PM. Therefore, the control device 80 may allocate a plurality of transfer periods so that the plurality of transfer periods are sparse with each other in the supply interval of wafers W.

Specifically, the number of transfer timing charts obtained as a result of solving the problem in the period calculation step S1 is not limited to one, and a plurality of transfer timing charts that satisfy the constraint conditions may be obtained. The control device 80 finally selects one solution having the strongest resistance to a delay in the substrate processing from among the plurality of solution candidates. For example, the control device 80 has an objective function of equalizing the time intervals (use intervals described later) between a plurality of transfer periods in which the transfer module TM is used. Then, the control device 80 adds another constraint condition to the constraint that maximizes the throughput solved in the period calculation step S1, and solves the objective function and the constraint conditions using a linear programming problem (mixed integer programming problem). This makes it possible for the control device 80 to select a solution in which the plurality of transfer periods in the transfer module TM are sparse from each other (equalized).

By performing the period calculation step S1 and the allocation step S2 described above, the control device 80 may obtain the supply interval of wafers W and the plurality of transfer periods that maximize the throughput. Further, in the supply interval of wafers W thus calculated, two conditions are satisfied in which the transfer periods of the wafers W do not overlap and the resistance to a delay in the stay period of the process module PM is strong.

It is preferable that the control device 80 performs scheduling in the allocation step S2 by considering a practically-excluded additional condition so as not to include weak solutions that would fail with a slight delay. An example of the additional condition is that the waiting period in the process module PM is scheduled to be 0 second. To deal with this, the control device 80 may be able to specify a minimum waiting period as a parameter so that the waiting period does not become 0 second. Another example of the additional condition is that each use interval (TM use interval) of the transfer module TM is scheduled to be 0 second. To deal with this, the control device 80 may be able to specify a minimum transfer period as a parameter so that the transfer period does not become 0 second.

The scheduling of wafers W (substrate transfer processing method) by the control device 80 will be described in more detail. In the period calculation step S1, when the supply interval of wafers W is formulated as a mixed integer programming problem, the objective function is as follows.
Objective function: minimizing the supply interval of wafers W

Further, the constraint conditions may be the following (A) and (B).
Constraint conditions: (A) a plurality of transfer periods of the transfer modules TM do not overlap; and (B) the stay period of each process module PM falls within a range that does not exceed the supply interval of wafers W, and also satisfies requirements such as replacement of wafers W and immediate unloading of wafers W.

In addition, the reason why the stay period of each process module PM is set to fall within a range that does not exceed the supply interval of wafers W in constraint condition (B) is that if the stay period exceeds the supply interval of wafers W, the process module PM causes a blockage in the transfer of wafers W.

In addition, variables for the mixed integer programming problem may be the following (a) to (c).
Variables: (a) Supply interval of wafers W
(b) Stay period of each process module PM
(c) Temporary variables for expressing logical conditions

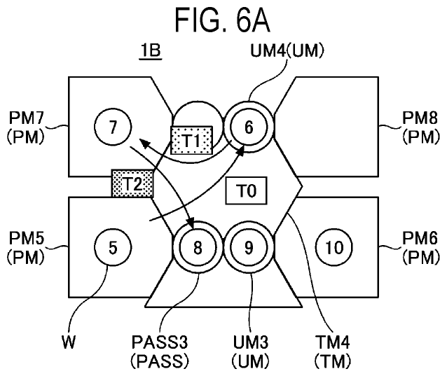

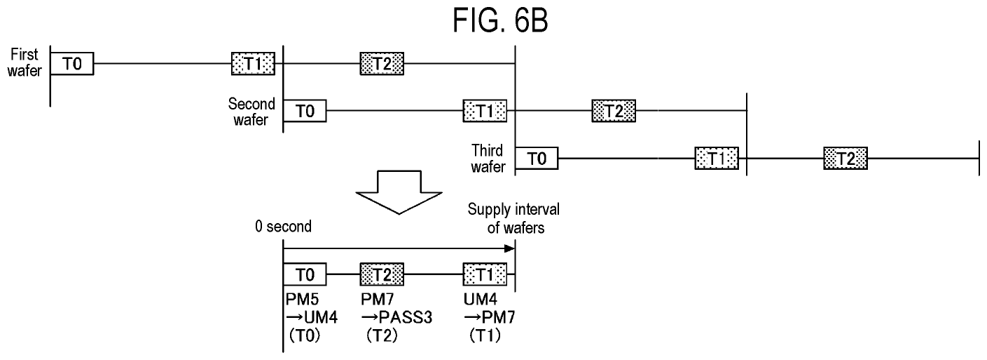

A substrate transfer processing method according to the present embodiment will be described below in detail by using the substrate processing system 1B of the second configuration example as an example. FIG. 6A is an enlarged plan view showing the configuration of the fourth transfer module TM4 and its surroundings in the substrate processing system 1B according to the second configuration example. First, the fourth transfer module TM4 of the substrate processing system 1B will be described.

As shown in FIG. 6A, the fourth transfer module TM4 of the substrate processing system 1B has an opportunity to transfer the wafer W three times. The first transfer period T0 is a period during which the transfer robot 32B of the fourth transfer module TM4 transfers the wafer W from the fifth process module PM5 to the fourth retraction module UM4. The second transfer period T1 is a period during which the wafer W is transferred from the fourth retraction module UM4 to the seventh process module PM7. The third transfer period T2 is a period during which the wafer W is transferred from the seventh process module PM7 to the third passage module PASS3.

In the fourth transfer module TM4, as shown in FIG. 6B, a plurality of wafers W are transferred at a constant rhythm (supply interval of wafers W). For example, during the stay period of the seventh process module PM7 after a first wafer W has been transferred to the seventh process module PM7, the transfer of a second wafer W is started. In this case, the transfer of a third wafer W will be similarly started during the stay period of the seventh process module PM7 after the second wafer W has been transferred to the seventh process module PM7. When these transfer periods of wafers W are overlapped in one cycle, as shown in the lower diagram of FIG. 6B, it is possible to obtain a supply interval of one wafer W in which the first transfer period T0, the second transfer period T1 and the third transfer period T2 are included.

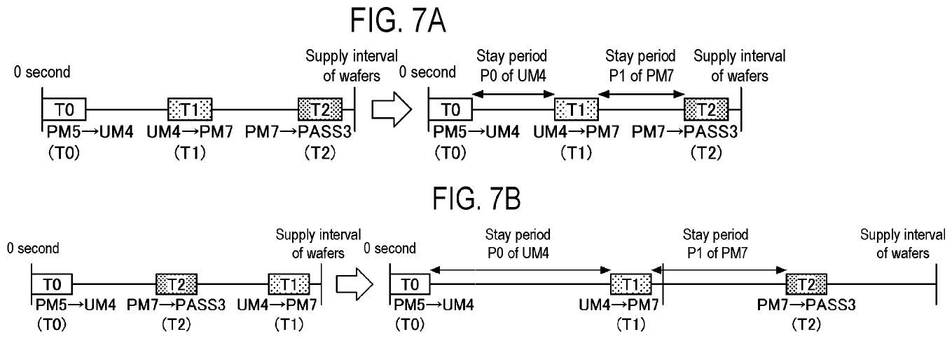

The transfer patterns of wafers W in the fourth transfer module TM4 are two patterns (pattern 0 and pattern 1) as shown in FIGS. 7A and 7B. FIG. 7A is a diagram showing pattern 0 in the fourth transfer module TM4. FIG. 7B is a diagram showing pattern 1 in the fourth transfer module TM4.

Pattern 0 shown in FIG. 7A is a transfer pattern in which the first transfer period T0, the second transfer period T1 and the third transfer period T2 are arranged in the named order. In the case of pattern 0, the first stay period P0 of the fourth retraction module UM4 (use interval of the transfer module TM) and the second stay period P1 of the seventh process module PM7 (use interval of the transfer module TM) are shortened. That is, if the stay period of each process module PM≤the supply interval of wafers W−the transfer period using the process module PM is used as the constraint conditions, the stay period of each process module PM may be shortened. Therefore, the first stay period P0 of the fourth retraction module UM4 and the second stay period P1 of the seventh process module PM7 are always short.

On the other hand, pattern 1 shown in FIG. 7B is a transfer pattern in which the first transfer period T0, the third transfer period T2 and the second transfer period T1 are arranged in the named order. In the case of pattern 1, there is a possibility that the first stay period P0 of the fourth retraction module UM4 and the second stay period P1 of the seventh process module PM7 are long.

In either pattern 0 or pattern 1 described above, if the plurality of transfer periods of the fourth transfer module TM4 do not overlap, then the supply interval of wafers W and the stay period of each module will become the desired values. Therefore, the conditions that the transfer periods of the fourth transfer module TM4 do not overlap in pattern 0 and pattern 1 are expressed by the following formulae.

(A) Formula for implementing the second transfer period T1 after the first transfer period T0 in pattern 0:

$$T 0 ≦ T 0 + P 0 ( P 0 = stay period of fourth retraction module UM 4 ) \qquad ( 1 )$$

If formula (1) is modified, 0≤P0. Since the stay period of the fourth retraction module UM4 is 0 second or more, this formula is always satisfied.

(B) Formula for implementing the third transfer period T2 after the second transfer period T1 in pattern 0:

$$T 0 + P 0 + T 1 ≦ T 0 + P 0 + T 1 + P 1 ( P 1 = stay period of seventh process module PM 7 ) \qquad ( 2 )$$

If formula (2) is modified, 0≤P1. Since the stay period of the seventh process module PM7 is 0 second or more, this formula is always satisfied.

(C) Formula for implementing the third transfer period T2 before the supply interval of wafers W in pattern 0:

$$T 0 + P 0 + T 1 + P 1 + T 2 ≦ supply interval of wafer W \qquad ( 3 )$$

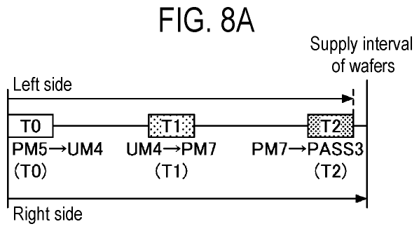

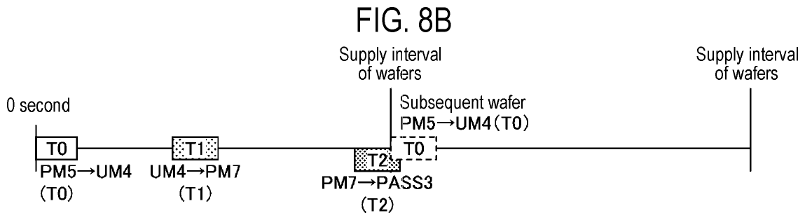

The left side of formula (3) is the range up to the first transfer period T0, the second transfer period T1 and the third transfer period T2 shown in FIG. 8A. On the other hand, the right side of formula (3) has the range (the supply interval of wafers W) shown in FIG. 8A. For example, when the timing of the third transfer period T2 is delayed, under a situation where a plurality of wafers W are sequentially transferred in the fourth transfer module TM4, as shown in FIG. 8B, the condition is no longer satisfied because the first transfer period T0 of the subsequent wafer W overlaps with the third transfer period T2.

(D) Formula for implementing the third transfer period T2 after the first transfer period T0 in pattern 1:

$$T 0 ≦ T 0 + P 0 + T 1 + P 1 - supply interval of wafer W \qquad ( 4 )$$

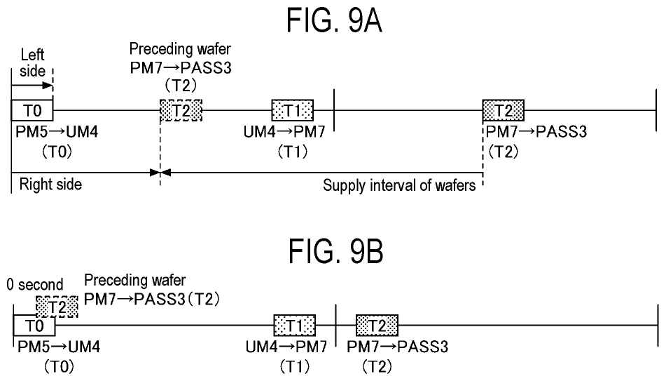

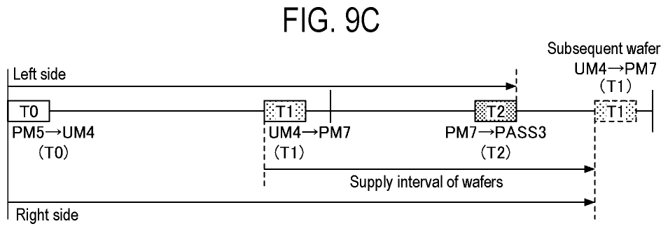

The left side of formula (4) is the range of the first transfer period T0 shown in FIG. 9A. The right side of formula (4) is the range of the first transfer period T0 and the first stay period P0 of the fourth retraction module UM4 shown in FIG. 9A. For example, when the timing of the third transfer period T2 is delayed, under a situation where a plurality of wafers W are sequentially transferred in the fourth transfer module TM4, as shown in FIG. 9B, the condition is no longer satisfied because the third transfer period T2 of the subsequent wafer W overlaps with the first transfer period T0.

(E) Formula for implementing the second transfer period T1 after the third transfer period T2 in pattern 1:

$$T 0 + P 0 + T 1 + P 1 + T 2 ≦ T 0 + P 0 + supply interval of wafer W \qquad ( 5 )$$

The left side of formula (5) is the range up to the first transfer period T0, the second transfer period T1 and the third transfer period T2 shown in FIG. 9C. Further, the right side of formula (5) is the range (the supply interval of wafers W) shown in FIG. 9C.

(F) Formula for implementing the first transfer period T0 before the supply interval of wafers W in pattern 1

$$T 0 + P 0 + T 1 ≦ supply interval of wafer W \qquad ( 6 )$$

The control device 80 may prevent a plurality of transfer periods from overlapping in the fourth transfer module TM4 if the constraint conditions are satisfied in either of the transfer patterns of pattern 0 and pattern 1 described above. For example, by using a big-M method, the control device 80 may formulate either pattern 0 or pattern 1 as the following constraint conditions.

$$Formula ( 1 ) + M \times BoolPatternTM4\_ 0 \\ Formula ( 2 ) + M \times BoolPatternTM4\_ 0 \\ Formula ( 3 ) + M \times BoolPatternTM4\_ 0 \\ Formula ( 4 ) + M \times BoolPatternTM4\_ 1 \\ Formula ( 5 ) + M \times BoolPatternTM4\_ 1 \\ Formula ( 6 ) + M \times BoolPatternTM4\_ 1 \\ BoolPatternTM4\_ 0 = 0 or 1 ( variable that becomes 0 if \\ pattern 0 is selected and becomes 1 if not selected ) \\ BoolPatternTM4\_ 1 = 0 or 1 ( variable that becomes \\ 0 if pattern 1 is selected and becomes 1 if not selected ) \\ BoolPatterTM4\_ 0 + BoolPatternTM4\_ 1 = 1 ( constraint for \\ satisfying only either pattern 0 or pattern 1 )$$

Next, the third transfer module TM3 of the substrate processing system 1B will be considered. The third transfer module TM3 has an opportunity to transfer the wafer W four times (see FIG. 3). The first transfer period T0 is a period during which the transfer robot 32B of the third transfer module TM3 transfers the wafer W from the third process module PM3 to the fifth process module PM5. The second transfer period T1 is a period during which the wafer W is transferred from the third passage module PASS3 to the third retraction module UM3. The third transfer period T2 is a period during which the wafer W is transferred from the third retraction module UM3 to the sixth process module PM6. The fourth transfer period T3 is a period during which the wafer W is transferred from the sixth process module PM6 to the second passage module PASS2.

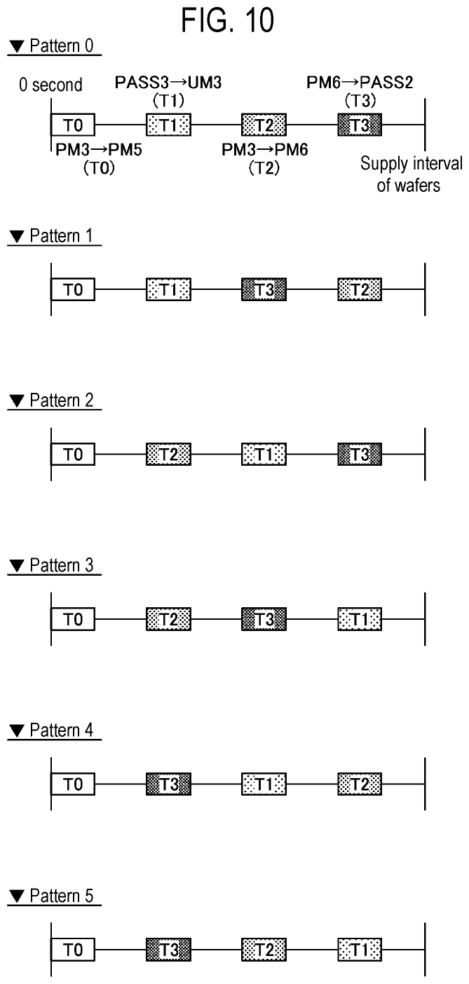

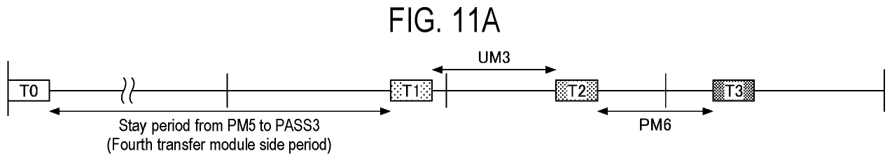

Further, the third transfer module TM3 also transfers a plurality of wafers W at a constant rhythm. It is conceivable that the third transfer module TM3 adopts six transfer patterns (pattern 0 to pattern 5) as shown in FIG. 10. Pattern 0 is a transfer pattern in which the first transfer period T0, the second transfer period T1, the third transfer period T2, and the fourth transfer period T3 are arranged in the named order. Pattern 1 is a transfer pattern in which the first transfer period T0, the second transfer period T1, the fourth transfer period T3, and the third transfer period T2 are arranged in the named order. Pattern 2 is a transfer pattern in which the first transfer period T0, the third transfer period T2, the second transfer period T1, and the fourth transfer period T3 are arranged in the named order. Pattern 3 is a transfer pattern in which the first transfer period T0, the third transfer period T2, the fourth transfer period T3, and the second transfer period T1 are arranged in the named order. Pattern 4 is a transfer pattern in which the first transfer period T0, the fourth transfer period T3, the second transfer period T1, and the third transfer period T2 are arranged in the named order. Pattern 5 is a transfer pattern in which the first transfer period T0, the fourth transfer period T3, the third transfer period T2, and the second transfer period T1 are arranged in the named order.

In any of these transfer patterns, if the plurality of transfer periods of the third transfer module TM3 do not overlap, then the supply interval of wafers W and the stay period of each process module PM will become desired values. In the following, the conditions in which a plurality of transfer periods do not overlap in pattern 5 of the third transfer module TM3 will be representatively expressed by the following formulae, and the descriptions of other patterns will be omitted.

(G) Formula for implementing the second transfer period T1 before the supply interval of wafers W:

first transfer period T0+(stay period P0 of fifth process module PM5+first transfer period T0 of fourth transfer module TM4+first stay period P0 of fourth retraction module UM4+second transfer period T1 of fourth transfer module TM4+second stay period P1 of seventh process module PM7+third transfer period T2 of fourth transfer module TM4+third stay period P2 of third passage module PASS3)+second transfer period T1≤supply interval of wafer W×(N+1) (7)

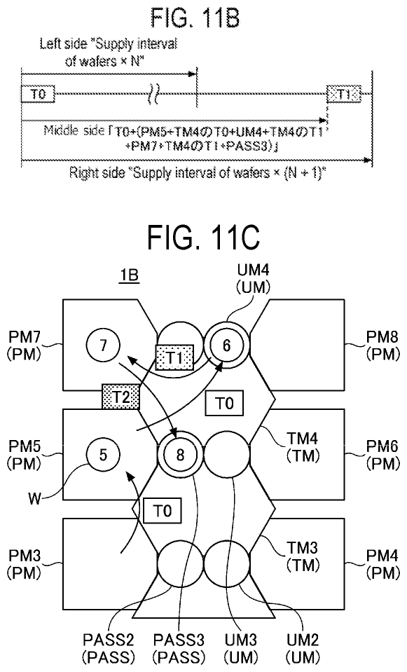

As shown in FIG. 11A and FIG. 11C, the value in parentheses in formula (7) indicates the “fourth transfer module side period” from the stay period P0 of the fifth process module PM5 to the third stay period P2 of the third passage module PASS3 by the fourth transfer module TM4. The left side of formula (7) is a formula that includes the fourth transfer module side period in addition to the first transfer period T0 and the second transfer period T1, and the right side of formula (7) indicates that the supply period of wafers W in the third transfer module TM3 is longer than that on the left side of formula (7).

(H) Regarding the variable N used in the formula for implementing the second transfer period T1 before the supply interval of wafers W

N is defined as a variable of an integer indicating “the magnification of a starting point of a first transfer returned from the fourth transfer module TM4 relative to the supply interval of wafers W when the third transfer module TM3 is used as the starting point of the first transfer”. This may be expressed by the following formula (8):

$$supply interval of wafer W \times N ≦ first transfer period T 0 + ( fourth transfer module side period ) ≦ supply interval of wafer W \times ( N + 1 ) \qquad ( 8 )$$

The left side of formula (8) is a predetermined range between the first transfer period T0 and the second transfer period T1 as shown in FIG. 11B. The middle side of formula (8) is a range that includes the fourth transfer module side period from the start of the first transfer period T0 to before the second transfer period T1 (see also FIG. 11C). The right side of formula (8) is the range from the start of the first transfer period T0 to beyond the second transfer period T1.

(I) Formula for implementing the fourth transfer period T3 after the first transfer period T0:

$$first transfer period T 0 ≦ first transfer period T 0 + \qquad ( 9 )$$

$$( fourth transfer module side period ) + second transfer period T 1 +$$

$$stay period P 1 of third retraction module UM 3 +$$

$$third transfer period T 2 + stay period P 2 of sixth process module PM 6 -$$

$$supply interval of wafer W \times ( N + 2 )$$

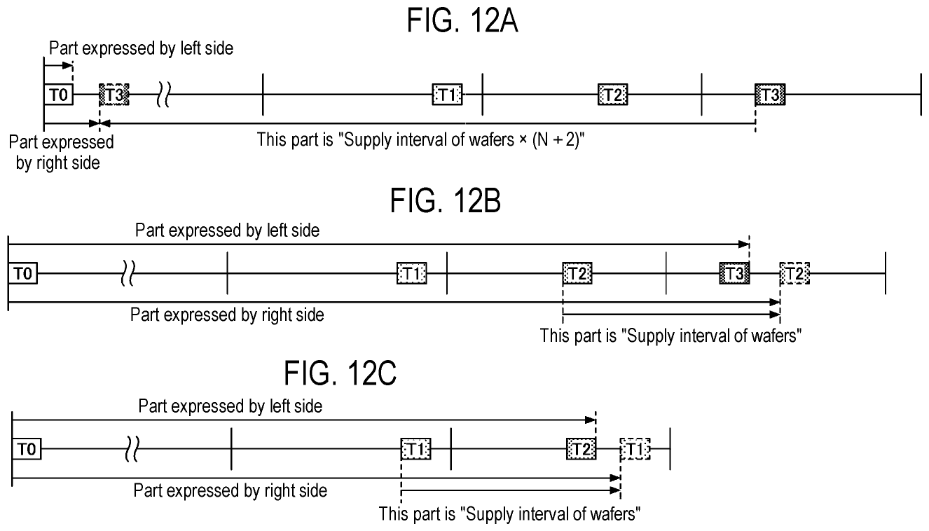

The left side of formula (9) is the range of the first transfer period T0 as shown in FIG. 12A. On the other hand, the right side of formula (9) is the range from the first transfer period T0 to the fourth transfer period T3 for the subsequent wafer W.

(J) Formula for implementing the third transfer period T2 after the fourth transfer period T3:

$$first transfer period T 0 + ( fourth transfer module side period ) + \qquad ( 10 )$$

$$second transfer period T 1 +$$

$$stay period P 1 of third retraction module UM 3 +$$

$$third transfer period T 2 +$$

$$stay period P 2 of sixth process module PM 6 +$$

$$fourth transfer period T 3 ≦ first transfer period T 0 +$$

$$( fourth transfer module side period ) + second transfer period T 1 +$$

$$stay period P 1 of third retraction module UM 3 +$$

$$supply interval of wafer W$$

The left side of formula (10) is the range from the start of the first transfer period T0 to the end of the fourth transfer period T3 as shown in FIG. 12B. On the other hand, the right side of formula (10) is the range from the start of the first transfer period T0 to the start of the third transfer period T2 of the subsequent wafer W. The supply interval of wafers W corresponds to an interval from the start of the third transfer period T2 of the first wafer W to the start of the third transfer period T2 of the second wafer W.

(K) Formula for implementing the second transfer period T1 after the third transfer period T2:

$$first transfer period T 0 + ( fourth transfer module side period ) + second transfer period T 1 + stay period P 1 of third retraction module UM 3 + third transfer period T 2 ≦ first transfer period T 0 + ( fourth transfer module side period ) + supply interval of wafer W \qquad ( 11 )$$

The left side of equipment (11) is the range from the start of the first transfer period T0 to the end of the third transfer period T2 as shown in FIG. 12C. On the other hand, the right side of formula (11) is the range from the start of the first transfer period T0 to the start of the second transfer period T1 of the subsequent wafer W. The supply interval of wafers W corresponds to an interval from the start of the second transfer period T1 of the first wafer W to the start of the second transfer period T1 of the second wafer W.

Just like pattern 5 described above, the control device 80 may formulate formulae for patterns 0 to 4 which indicate that the plurality of transfer periods do not overlap in the third transfer module TM3. If the constraint conditions are satisfied in any one of these transfer patterns from pattern 0 to pattern 5, it is possible to prevent the plurality of transfer periods of the third transfer module TM3 from overlapping. For example, by using a big-M method, the control device 80 may similarly formulate the fourth transfer module TM4 using any of patterns 0 to 5 as constraint conditions.

Next, the formulation of OR transfer by the transfer module TM of the substrate processing system 1B will be described. In the OR transfer, the wafer W is transferred to either of the two process modules PM. The same concept may be applied to the case where the wafer W is transferred to any of three or more process modules PM. Specifically, in the OR transfer of two process modules PM, the stay period of the process module PM may be selected within the range of two cycles in the supply interval of wafers W. In this case, the following two steps are performed to obtain the value.

Step 1: Prepare a temporary stay period that falls within one cycle of the supply interval of wafers W, and solve the formula.

Step 2: Adjust the obtained temporary stay period so that it falls within the range of two cycles of the supply interval of wafers W, and find the final stay period.

First, in step 1, the control device 80 calculates a temporary stay period so that it may be calculated within the range of the supply interval of wafers W. However, there may be a case where the process module PM that performs the OR transfer is an immediate unloading process module PM. The phrase “immediate unloading” refers to unloading a wafer W from a process module PM after a substrate processing is performed in the process module PM.

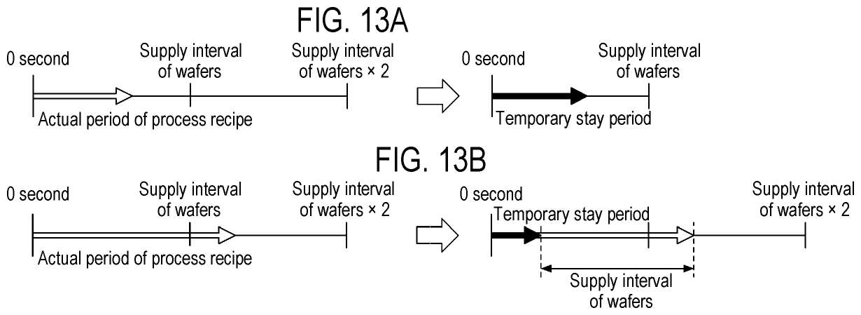

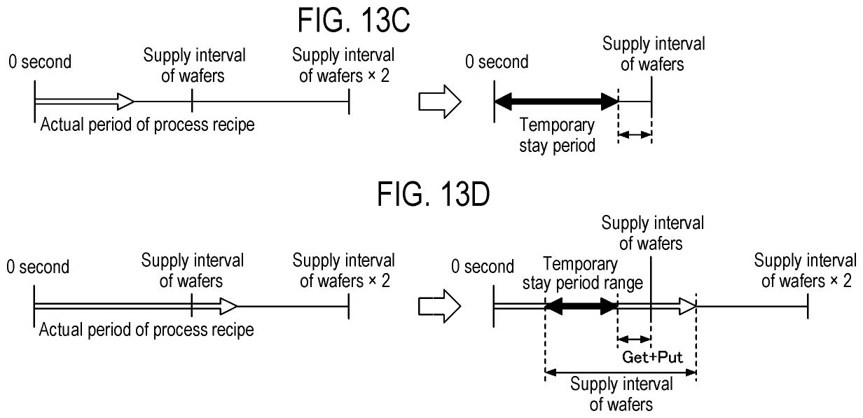

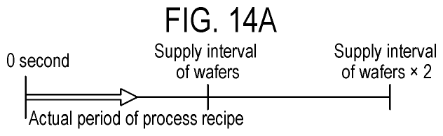

If the OR transfer process module PM is an immediate unloading process module PM, and if the actual period of the process recipe is shorter than or equal to the supply interval of wafers W (in other words, if the actual period of the process recipe is short), then the following formula (12) may be used as the temporary stay period. Further, this concept may be indicated as a bar graph of time as shown in FIG. 13A.

$$Temporary stay period of process module PM = actual period of process recipe \qquad ( 12 )$$

On the other hand, if the OR transfer process module PM is an immediate unloading process module PM and if the actual period of the process recipe is longer than the supply interval of wafers W (in other words, if the actual period of the process recipe is long), then the following formula (13) may be used as the temporary stay period. Further, this concept may be indicated as a bar graph of time as shown in FIG. 13B.

$$Temporary stay period of process module PM = actual period of process recipe - supply interval of wafer W \qquad ( 13 )$$

Further, there is a case where the process module PM that performs the OR transfer is a process module PM that performs replacement (unloading and loading) of wafers W. In this case, the following formula (14) may be used as the temporary stay period.

$$Temporary stay period of process module PM = supply interval of wafers W - period of unloading wafer W from process module PM - period of loading wafer W into process module PM \qquad ( 14 )$$

Further, the process module PM that performs the OR transfer may be a process module PM used when the wafer W is unloaded from one transfer module TM and loaded into another transfer module TM (however, the immediate unloading process module PM is excluded). Hereinafter, this process module PM will also be referred to as a feeding process module PM.

In the case of the feeding process module PM, if the actual period of the process recipe is shorter than or equal to the supply interval of wafers W (that is, if the actual period of the process recipe is short), the following formula (15) may be used as the temporary stay period. Further, this concept may be indicated as a bar graph of time as shown in FIG. 13C.

$$0 ≦ temporary stay period of process module PM ≦ supply of wafer W - period of unloading wafer W from process module PM - period of loading wafer W into process module PM \qquad ( 15 )$$

On the other hand, if the process module PM is a feeding process module PM and if the actual period of the process recipe is longer than the supply interval of wafers W (that is, if the actual period of the process recipe is long), the following formula (16) may be used as the temporary stay period. Further, this concept may be indicated as a bar graph of time as shown in FIG. 13D.

$$Actual period of process recipe - supply interval of wafer W ≦ temporary stay period of process module PM ≦ supply interval of wafer W - period of unloading wafer W from process module PM - period of loading wafer W into process module PM \qquad ( 16 )$$

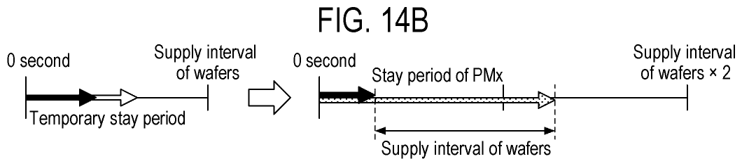

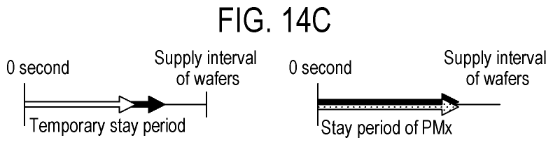

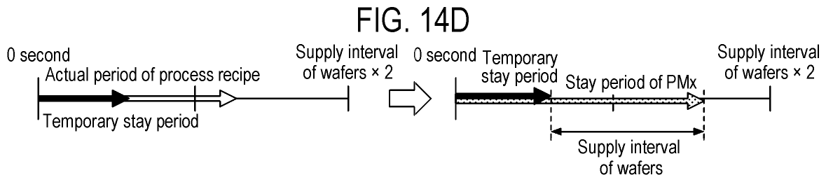

In step 1, the control device 80 calculates temporary stay periods for the plurality of patterns described above, and then, in step 2, calculates a final stay period. The formula for calculating the final stay period may be divided into a case where the actual period of the process recipe≤the supply interval of wafers W and a case where the actual period of the process recipe>the supply interval of wafers W, as shown in FIG. 14A.

Further, if the actual period of the process recipe is shorter than the supply interval of wafers W and if the temporary stay period of the process module PM is shorter than the actual period of the process recipe, the following formula (17) may be used. Further, this concept may be indicated as a bar graph of time as shown in FIG. 14B.

$$Stay period of process module PM = temporary stay period of process module PM + supply interval of wafer W \qquad ( 17 )$$

On the other hand, if the actual period of the process recipe is shorter than the supply interval of wafers W and if the temporary stay period of the process module PM is longer than or equal to the actual period of the process recipe, the following formula (18) may be used. Further, this concept may be indicated as a bar graph of time as shown in FIG. 14C.

$$Stay period of process module PM = temporary stay period of process module PM \qquad ( 18 )$$

If the actual period of the process recipe is longer than the supply interval of wafers W, the following formula (19) may be used. Further, this concept may be indicated as a bar graph of time as shown in FIG. 14D.

$$Stay period of process module PM = temporary stay period of process module PM + supply interval of wafer W \qquad ( 19 )$$

Further, the stay period of the process module PM that performs immediate unloading other than OR transfer is expressed by the following formula (20).

$$Stay period of process module PM = actual period of process recipe \qquad ( 20 )$$

Further, the stay period of the process module PM that performs replacement (unloading and loading) of wafers W other than OR transfer is expressed by the following formula (21). That is, in the case of the process module PM that performs replacement, the process recipe only needs to be completed at the timing when the wafer W is supplied.

$$Stay period of process module PM = supply interval of wafer W - period of unloading wafer W from process module PM - period of loading wafer W into process module PM \qquad ( 21 )$$

Further, the stay period of the process module PM that performs feeding other than OR transfer is expressed by the following formula (22).

$$Actual period of process recipe ≦ stay period of process module PM ≦ supply interval of wafer W - period of unloading wafer W from process module PM - period of loading wafer W into process module PM \qquad ( 22 )$$

When determining the optimum supply interval of wafers W, constraint condition formulae are formulated in the above-described patterns for all of the first to fourth transfer modules TM1 to TM4. In other words, a formula in which the transfer periods of the fourth transfer module TM4 do not overlap, a formula in which the transfer periods of the third transfer module TM3 do not overlap, a formula in which the transfer periods of the second transfer module TM2 do not overlap, and a formula in which the transfer periods of the first transfer module TM1 do not overlap are formulated. In addition, a formula which indicates that the stay period of each process module PM is appropriate is formulated.

Further, as mentioned above, the objective function for maximizing the throughput is to minimize the supply interval of wafers W, and the variables thereof include the supply interval of wafers W, the stay period of the process module PM, and the temporary variable or auxiliary variable for expressing logical conditions.

Next, the allocation step S2 in the scheduling of the wafer W (substrate transfer processing method) will be described. As described above, if the intervals between the transfer periods during which the transfer modules TM operate are close to each other, a slight delay may disrupt the transfer (see also the left diagram in FIG. 5). Therefore, in the allocation step S2, the stay period of the process module PM is determined based on the supply interval of wafers W determined in the period calculation step S1, so that the intervals between the respective transfer periods of the transfer module TM are far apart.

However, the calculation in the allocation step S2 is similar to the calculation in the period calculation step S1. The differences lie in that the objective function is to equalize the use intervals (transfer period intervals) of the transfer modules TM, that the constraint conditions include an auxiliary formula for equalizing the use intervals of each transfer module TM, and that the variables include an additional variable for equalizing the use intervals of the transfer module TM. In the allocation step S2, the supply interval of the wafers W is not a variable but a constant.

In the auxiliary formula for equalizing the use intervals of each transfer module TM, the use intervals of each transfer module TM are determined. For example, in the case of the fourth transfer module TM4, the time interval between the first transfer period T0 and the second transfer period T1, the time interval between the second transfer period T1 and the third transfer period T2, and the time interval between the third transfer period T2 and the first transfer period T0 are the use intervals.

The use intervals of the transfer modules TM may be determined by transforming the above-mentioned “condition for the transfer modules TM not to transfer at the same time” into “the right side minus the left side.” For example, formula (5) when implementing the second transfer period T1 after the third transfer period T2 in pattern 1 of the fourth transfer module TM4 becomes the following formula (23). In formula (23), the time difference between the third transfer period T2 and the second transfer period T1 in pattern 1 of the fourth transfer module TM4 is expressed as “IntervalTM4P1_T2_T1.” That is, “IntervalTMxPy_Tv_Tw” represents the time difference from Tv to Tw in pattern y of a predetermined transfer module TM.

$$IntervalTM4P1\_T2 \_T1 = ( T 0 + P 0 + supply interval of wafer W ) - ( T 0 + P 0 + T 1 + P 1 + T 2 ) \qquad ( 23 )$$

Further, the use interval from the first transfer period T0 to the third transfer period T2 in pattern 1 of the fourth transfer module TM4 is expressed by the following formula (24).

$$IntervalTM4P1\_T0 \_T2 = ( T 0 + P 0 + T 1 + P 1 - supply interval of wafer W ) - T 0 \qquad ( 24 )$$

Similarly, the use interval from the third transfer period T2 to the second transfer period T1 in pattern 1 of the fourth transfer module TM4 is expressed by the following formula (25).

$$IntervalTM4P1\_T2 \_T1 = ( T 0 + P 0 + supply interval of wafer W ) - ( T 0 + P 0 + T 1 + P 1 + T 2 ) \qquad ( 25 )$$

The use interval from the second transfer period T1 to the first transfer period T0 in pattern 1 of the fourth transfer module TM4 is expressed by the following formula (26).

$$IntervalTM4P1\_T1 \_T0 = supply interval of wafer W - ( T 0 + P 0 + T 1 ) \qquad ( 26 )$$

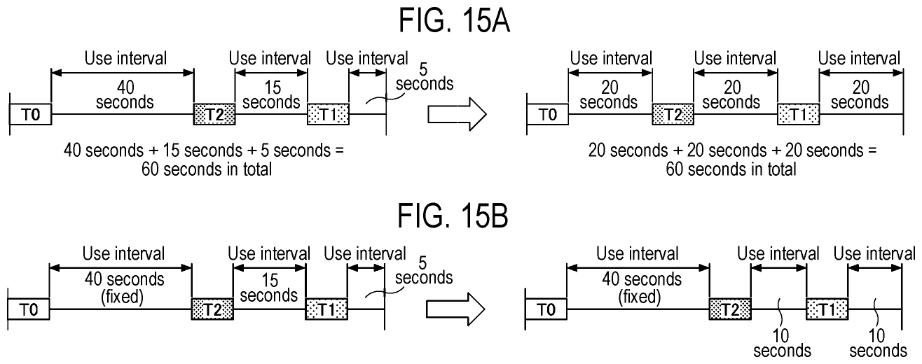

As shown in FIG. 15A, the use intervals of the transfer module TM are shared by the respective transfer modules TM. For example, if the total use interval is 60 seconds, the 60 seconds are shared. Due to this condition, equalizing is performed by preventing an extremely long use interval from appearing. For example, since there is a large interval of 40 seconds as shown in the left diagram of FIG. 15A, equalizing is performed to reduce this interval as shown in the right diagram of FIG. 15A. Oher equalizing methods such as increasing the minimum use interval may be used.

Further, when equalizing the use intervals, a constraint formula using a new variable Z_TMx is added so that the use interval of each transfer module TM alone does not become large. For example, the formulae for preventing the use interval of the fourth transfer module TM4 from becoming too long are as follows.

In the case of pattern 0,

$$IntervalTM4P0\_T0 \_T1 - M \times BoolPatternTM4\_ 0 ≦ Z\_TM4 , \\ IntervalTM4P0\_T1 \_T2 - M \times BoolPatternTM4\_ 0 ≦ Z\_TM4 , and \\ IntervalTM4P0\_T2 \_T0 - M \times BoolPatternTM4\_ 0 ≦ Z\_TM4 . \\ In the case of pattern 1 , \\ IntervalTM4P1\_T0 \_T2 - M \times BoolPatternTM4\_ 1 ≦ Z\_TM4 , \\ IntervalTM4P1\_T2 \_T1 - M \times BoolPatternTM4\_ 1 ≦ Z\_TM4 , and \\ IntervalTM4P1\_T1 \_T0 - M \times BoolPatternTM4\_ 1 ≦ Z\_TM4 .$$

The constraint formula using this new variable Z_TMx is similarly applied to the first transfer module TM1 to the third transfer module TM3.

Due to the constraint added in the above-mentioned “formula for preventing the use interval of each transfer module TM alone from becoming large”, the TM use intervals are equalized to some extent. However, when an immediate unloading process module PM exists, there is a part where the use interval does not change. If this is the maximum value, other use intervals may not be equalized. For example, if the use period between the first transfer period T0 and the second transfer period T1 in the left diagram of FIG. 15B is fixed to 40 seconds due to immediate unloading, the use interval between the third transfer period T2 and the second transfer period T1 and the use interval between the second transfer period T1 and the first transfer period T0 are not equalized in the above-described formulae.

Therefore, in order to equalize the use intervals other than the maximum value, the control device 80 limits the sum of the respective use intervals. By limiting the sum, the effect of equalization occurs also in the parts other than the maximum value. As a result, as shown in the right diagram of FIG. 15B, the use interval between the third transfer period T2 and the second transfer period T1 and the use interval between the second transfer period T1 and the first transfer period T0 other than fixed use intervals are equalized. Specifically, in the constraint conditions, a constraint formula using a new variable Zpair_TMx is added so that the sum of use intervals does not become large. For example, the formulae for preventing the use interval of the fourth transfer module TM4 from becoming too long are as follows.

In the case of pattern 0,

$$IntervalTM4P0\_T0 \_T1 + IntervalTM4P0\_T1 \_T2 - M \times BoolPatternTM4\_ 0 ≦ Zpair\_TMx \\ IntervalTM4P0\_T0 \_T1 + IntervalTM4P0\_T2 \_T0 - M \times BoolPatternTM4\_ 0 ≦ Zpair\_TMx \\ IntervalTM4P0\_T1 \_T2 + IntervalTM4P0\_T2 \_T0 - M \times BoolPatternTM4\_ 0 ≦ Zpair\_TMx \\ In the case of pattern 1 , \\ IntervalTM4P1\_T0 \_T2 + IntervalTM4P1\_T2 \_T1 - M \times BoolPatternTM4\_ 1 ≦ Zpair\_TMx \\ IntervalTM4P1\_T0 \_T2 + IntervalTM4P1\_T1 \_T0 - M \times BoolPatternTM4\_ 1 ≦ Zpair\_TMx \\ IntervalTM4P1\_T2 \_T1 + IntervalTM4P1\_T1 \_T0 - M \times BoolPatternTM4\_ 1 ≦ Zpair\_TMx$$

The above constraint formulae using the new variable Zpair_TMx may be similarly applied to the first to third transfer modules TM1 to TM3.

In the allocation step S2, the objective function for determining the optimum stay period of the process module PM is “equalizing the use interval of the transfer module TM.” This is achieved by ensuring that no extremely long use interval appears. Therefore, the objective function is set to the following formula (27) so that the sum of Z_TMx and Zpair_TMx becomes small.

$$Objective function : Minimize ΣZ\_TMx + ΣZpair\_TMx \qquad ( 27 )$$

When determining the optimum stay period of the process module PM, the above-described constraint formulae are formulated for all of the first to fourth transfer modules TM1 to TM4. That is, the control device 80 formulates a formula for limiting the use period of the fourth transfer module TM4 so that it does not become too long, a formula for limiting the use period of the third transfer module TM3 so that it does not become long, a formula for limiting the use period of the second transfer module TM2 so that it does not become too long, and a formula for limiting the use period of the first transfer module TM1 so that it does not become too long.

Further, as described above, the above formula (27) may be applied as the objective function for equalizing the stay period of the process module PM. The variables include the supply interval of wafers W, the stay period of the process module PM, the temporary variables and auxiliary variables for expressing logical conditions, and the additional variables (Z_TMx and Zpair_TMx) for equalizing the use intervals of the transfer modules TM.

By performing the substrate transfer processing method up to the above allocation step S2, it is possible to obtain the stay periods of the process modules PM in which the plurality of transfer periods in each transfer module TM are not overlapped and are spaced apart from each other.

The substrate processing systems 1A and 1B, the control device 80, and the substrate transfer processing method according to the present embodiment are not limited to the above-described embodiments, and may take various modifications. For example, although the substrate processing systems 1A and 1B have four transfer modules TM, the number of transfer modules TM may be one, two, three, or five or more.

The technical ideas and effects of the present disclosure described in the above embodiments will be set forth below.

A first aspect of the present disclosure is directed to a substrate processing system 1A or 1B, including: one or more transfer modules TM configured to transfer substrates (wafers W); a plurality of process modules PM configured to perform a substrate processing on the substrates transferred by the one or more transfer modules TM; and a control device 80 configured to control the one or more transfer modules TM and the plurality of process modules PM, wherein the control device 80 sequentially performs (A) calculating a substrate supply interval for supplying the substrates in the one or more transfer modules TM so that substrate transfer periods during which the substrates are transferred do not overlap with each other, and (B) equalizing, based on the calculated substrate supply interval, a plurality of time intervals (use intervals) between the substrate transfer periods so that the substrate transfer periods are separated from each other.

According to the above configuration, even if the substrates (wafers W) are transferred along multiple types of complicated transfer paths in the one or more transfer modules TM, the substrate processing system 1A or 1B may minimize the substrate supply interval and may appropriately allocate the substrate transfer periods. As a result, the substrate processing system 1A or 1B may efficiently transfer the substrates while avoiding overlapping the transfer timings of the substrates in the one or more transfer modules TM.

Further, in (A), an objective function is set to minimize the substrate supply interval, and in all of the one or more transfer modules TM, the substrate supply interval is calculated by a linear programming problem using constraint conditions obtained by formulating a formula which indicates that the substrate transfer periods do not overlap with each other. As a result, the substrate processing system 1A or 1B may more appropriately calculate the substrate supply interval that may efficiently transfer the plurality of substrates while avoiding overlapping the transfer timings of the plurality of substrates in the transfer module TM.

Further, the constraint conditions for a predetermined transfer module TM among the one or more transfer modules TM use, as variables, the substrate supply interval and a stay period of the process module PM connected to the predetermined transfer module TM. As a result, the substrate processing system 1A or 1B may easily calculate the substrate supply interval using the linear programming problem.

Further, the constraint conditions for a predetermined transfer module TM among the one or more transfer modules TM include all of a plurality of types of transfer paths of the substrates (wafers W) in the predetermined transfer module TM, and include a plurality of patterns in which the order of the plurality of types of transfer paths is changed. As a result, the substrate processing system 1A or 1B may satisfactorily formulate the constraint conditions covering the plurality of types of transfer paths in the predetermined transfer module TM.

Further, in (B), an objective function is set to minimize at least one of a plurality of time intervals or the sum of the plurality of time intervals, and in all of the one or more transfer modules TM, the plurality of time intervals are equalized by a linear programming problem using constraint conditions obtained by formulating a formula which indicates that the plurality of time intervals do not become large. By using the linear programming problem in this way, the substrate processing system 1A or 1B may obtain a plurality of time intervals that are highly resistant to a delay in the stay period of the process module PM.

Further, the constraint conditions for a predetermined transfer module TM among the one or more transfer modules TM include, as variables, a stay period of the process module PM connected to the predetermined transfer module TM and an additional variable for equalizing a plurality of time intervals, and include, as a constant, the substrate supply interval. As a result, the substrate processing system 1A or 1B may easily calculate the plurality of time intervals using the linear programming problem.

Further, the constraint conditions for a predetermined transfer module TM among the one or more transfer modules TM include all of a plurality of types of transfer paths of substrates (wafers W) in the predetermined transfer module TM and a plurality of patterns in which the order of the plurality of types of transfer paths is changed, and include a formula which indicates that at least one of a plurality of time intervals in the predetermined transfer module TM or the sum of the plurality of time intervals do not become large. As a result, the substrate processing system 1A or 1B may satisfactorily formulate the constraint conditions for determining the plurality of time intervals.

Further, a passage module PASS is provided between the one or more transfer modules TM adjacent to each other so as to be capable of passing through a boundary between the adjacent transfer modules TM, and the control device 80 calculates the substrate supply interval and the plurality of time intervals so as to include a transfer period when the substrates (wafers W) pass through the passage module PASS. As a result, the substrate processing system 1A or 1B may schedule the transfer of the substrates by taking into consideration the transfer period during which the substrates are transferred to the passage module PASS.

Further, a retraction module UM capable of temporarily storing the substrates (wafers W) is connected to at least one of the one or more transfer modules TM, and the control device 80 calculates the substrate supply interval and the plurality of time intervals so as to include a transfer period when the substrates are transferred to and from the retraction module UM. As a result, the substrate processing system 1A or 1B may transfer the wafers W by effectively utilizing the retraction module UM.

Further, one of the one or more transfer modules TM to which the plurality of process modules PM are connected is capable of selecting one of the plurality of process modules PM to transfer the substrate (wafer W) thereto, and the control device 80 selects a stay period of the process module PM at a cycle of the substrate supply interval according to the number of the plurality of process modules PM. As a result, the substrate processing system 1A or 1B may satisfactorily perform the OR transfer for selectively transferring substrates to the plurality of process modules PM.

A second aspect of the present disclosure is directed to the control device 80 for the substrate processing system 1A or 1B that transfers substrates (wafers W) to the plurality of process modules PM by one or more transfer modules TM and performs a substrate processing on the substrates, wherein the control device 80 sequentially performs: (A) calculating a substrate supply interval for supplying the substrates in the one or more transfer modules TM so that substrate transfer periods during which the substrates are transferred do not overlap with each other; and (B) equalizing a plurality of time intervals (use intervals) between the substrate transfer periods based on the calculated substrate supply interval so that the substrate transfer periods are separated from each other.

A third aspect of the present disclosure is directed to the substrate transfer processing method for transferring the substrates (wafers W) to the plurality of process modules PM by one or more transfer modules TM and performing a substrate processing on the substrates, the method including sequentially performing: (A) calculating a supply interval of substrates for supplying a plurality of substrates in the one or more transfer modules TM so that substrate transfer periods during which the substrates are transferred do not overlap with each other; and (B) equalizing, based on the calculated substrate supply interval, a plurality of time intervals between the substrate transfer periods so that the substrate transfer periods are separated from each other. Even in the second and third aspects described above, it is possible to efficiently transfer a plurality of substrates while avoiding overlapping the transfer timings of the plurality of substrates in the transfer module TM.

According to the present disclosure in some embodiments, it is possible to efficiently transfer a plurality of substrates while avoiding overlapping the transfer timings of the substrates in a transfer module.

The substrate processing system 1A or 1B, the control device 80, and the substrate transfer processing method according to the embodiments disclosed herein are exemplary and not limitative in all respects. The embodiments may be modified and improved in various ways without departing from the scope and spirit of the appended claims. The matters described in the plurality of embodiments described above may be configured in other ways without being inconsistent, and may be combined without being inconsistent.

What is claimed is:

1. A substrate processing system, comprising:
one or more transfer modules configured to transfer substrates;
a plurality of process modules configured to perform a substrate processing on the substrates transferred by the one or more transfer modules; and
a control device configured to control the one or more transfer modules and the plurality of process modules,
wherein the control device sequentially performs:
calculating a substrate supply interval for supplying the substrates so that substrate transfer periods during which the substrates are transferred do not overlap with each other; and
equalizing, based on the calculated substrate supply interval, a plurality of time intervals between the substrate transfer periods so that the substrate transfer periods are separated from each other.

2. The substrate processing system of claim 1, wherein in the calculating the substrate supply interval, an objective function is set to minimize the substrate supply interval, and in all of the one or more transfer modules, the substrate supply interval is calculated by a linear programming problem using constraint conditions obtained by formulating a formula which indicates that the substrate transfer periods do not overlap with each other.

3. The substrate processing system of claim 2, wherein the constraint conditions for a predetermined transfer module among the one or more transfer modules use, as variables, the substrate supply interval and a stay period of the process module connected to the predetermined transfer module.

4. The substrate processing system of claim 2, wherein the constraint conditions for a predetermined transfer module among the one or more transfer modules include all of a plurality of types of substrate transfer paths in the predetermined transfer module, and include a plurality of patterns in which an order of the plurality of types of substrate transfer paths is changed.

5. The substrate processing system of claim 1, wherein in the equalizing the plurality of time intervals, an objective function is set to minimize at least one of the plurality of time intervals or a sum of the plurality of time intervals, and in all of the one or more transfer modules, the plurality of time intervals are equalized by a linear programming problem using constraint conditions obtained by formulating a formula which indicates that the plurality of time intervals do not become large.

6. The substrate processing system of claim 5, wherein the constraint conditions for a predetermined transfer module among the one or more transfer modules include, as variables, a stay period of the process module connected to the predetermined transfer module and an additional variable for equalizing the plurality of time intervals, and include, as a constant, the substrate supply interval.

7. The substrate processing system of claim 5, wherein the constraint conditions for a predetermined transfer module among the one or more transfer modules include all of a plurality of types of substrate transfer paths in the predetermined transfer module and a plurality of patterns in which an order of the plurality of types of substrate transfer paths is changed, and include a formula which indicates that at least one of the plurality of time intervals in the predetermined transfer module or the sum of the plurality of time intervals do not become large.

8. The substrate processing system of claim 3, further comprising a passage module provided between the one or more transfer modules adjacent to each other so as to be capable of passing through a boundary between the adjacent transfer modules,
wherein the control device is configured to calculate the substrate supply interval and the plurality of time intervals so as to include a transfer period when the substrates pass through the passage module.

9. The substrate processing system of claim 3, further comprising a retraction module configured to temporarily store the substrates and connected to at least one of the one or more transfer modules,
wherein the control device is configured to calculate the substrate supply interval and the plurality of time intervals so as to include a transfer period when the substrates are transferred to and from the retraction module.

10. The substrate processing system of claim 3, wherein one transfer module of the one or more transfer modules to which the plurality of process modules are connected is configured to select one process module of the plurality of process modules to transfer the substrate to the selected one process module, and
wherein the control device is configured to select a stay period of the selected process module in a cycle of the substrate supply interval according to a number of the plurality of process modules.

11. The substrate processing system of claim 1, further comprising a passage module provided between the one or more transfer modules adjacent to each other so as to be capable of passing through a boundary between the adjacent transfer modules,
wherein the control device is configured to calculate the substrate supply interval and the plurality of time intervals so as to include a transfer period when the substrates pass through the passage module.

12. The substrate processing system of claim 1, further comprising a retraction module configured to temporarily store the substrates and connected to at least one of the one or more transfer modules,
wherein the control device is configured to calculate the substrate supply interval and the plurality of time intervals so as to include a transfer period when the substrates are transferred to and from the retraction module.

13. The substrate processing system of claim 1, wherein one transfer module of the one or more transfer modules to which the plurality of process modules are connected is configured to select one process module of the plurality of process modules to transfer the substrate to the selected one process module, and
wherein the control device is configured to select a stay period of the selected process module in a cycle of the substrate supply interval according to a number of the plurality of process modules.

14. A control device for a substrate processing system that transfers substrates to a plurality of process modules by one or more transfer modules and performs a substrate processing on the substrates, wherein the control device sequentially performs:
calculating a substrate supply interval for supplying the substrates in the one or more transfer modules so that substrate transfer periods during which the substrates are transferred do not overlap with each other; and
equalizing, based on the calculated substrate supply interval, a plurality of time intervals between the substrate transfer periods so that the substrate transfer periods are separated from each other.

15. A substrate transfer processing method of transferring substrates to a plurality of process modules by one or more transfer modules and performing a substrate processing on the substrates, the substrate transfer processing method comprising sequentially performing:
calculating a substrate supply interval for supplying the substrates in the one or more transfer modules so that substrate transfer periods do not overlap with each other; and
equalizing, based on the calculated substrate supply interval, a plurality of time intervals between the substrate transfer periods so that the substrate transfer periods are separated from each other.
